(19) United States
(12) Patent Application Publication
(10) Pub. No.: US 2026/0123357 A1
(43) Pub. Date: Apr. 30, 2026

(54) PATTERN OVERLAY CORRECTION FOR INTEGRATED CIRCUIT FABRICATION

(71) Applicant: TEL Manufacturing and Engineering of America, Inc., Chaska, MN (US)

(72) Inventors: Robert William Heussner, Hillsboro, OR (US); Justin James Alexander, Hillsboro, OR (US); Rupali Singh Nigote, Hillsboro, OR (US)

(21) Appl. No.: 18/965,940

(22) Filed: Dec. 2, 2024

Related U.S. Application Data
(60) Provisional application No. 63/712,142, filed on Oct. 25, 2024.

(51) Int. Cl. H01L 21/66; G03F 7/00; G03F 7/40; H01L 21/311

(52) U.S. Cl. CPC H10P 74/203; G03F 7/40; G03F 7/70633; H10P 50/73

(57) ABSTRACT

A method for integrated circuit (IC) fabrication, where the method includes providing a substrate including a first patterned layer and a second patterned layer, where the second patterned layer is aligned to the first patterned layer; measuring an overlay error of the second patterned layer with the first patterned layer across the substrate; based on the measuring, obtaining the overlay error of the second patterned layer with the first patterned layer; and exposing the second patterned layer to a first flux from a first location specific directional process to correct the overlay error.

### CROSS-REFERENCE TO RELATED APPLICATIONS

This application claims the benefit of U.S. Provisional Application No. 63/712,142, filed on October 25, 2024, which application is hereby incorporated herein by reference.

### TECHNICAL FIELD

The present invention relates generally to a system and method for integrated circuit fabrication, and, in particular embodiments, to a system and method for pattern overlay correction.

### BACKGROUND

An integrated circuit (IC) is a network of electronic components integrated in a monolithic structure comprising a stack of various layers of materials formed by processing a starting substrate through a sequence of patterning levels. The processing at each patterning level may comprise deposition, lithography, and etching to form or modify miniature structures in a layer of the substrate. A lithography technique is first used to pattern features, such as lines, trenches, pillars and holes in a masking layer. The patterned mask is then used to process exposed portions of underlying layers. For example, the patterned mask may be used as an etch mask in a selective etch process to pattern an underlying layer, referred to as a layer-to-be-patterned for the etch process. The substrate is first coated with resist and then placed on a movable stage of a scanner in an optical lithography system. The system may generate a pattern of actinic radiation to expose the resist over a small area of the substrate, referred to as a die. By using a step-and-repeat function of the movable stage, multiple dies, arranged in a rectangular array, are exposed to the radiation pattern. With the resist thus exposed, the substrate is transferred to a developer, where the resist is developed to print a relief pattern, thus exposing a portion of a surface below. After printing the relief pattern, the pattern is transferred to underlying layers by selective etching using the patterned resist as an etch mask. Typically, adjacent below the resist, there is a bottom antireflective coating (BARC) formed over an optional hard mask layer formed over the layer-to-be-patterned. The BARC may also serve as a hard mask layer. In the absence of a hard mask layer, the relief pattern of the resist is transferred directly to the layer targeted for patterning. Or, the relief pattern may be first transferred to the hard mask layer by a first selective etch and thence to the layer targeted for patterning with a second selective etch using the hard mask as the etch mask. Then, for the first selective etch, the layer-to-be-patterned is the hard mask layer.

The structures fabricated in each of the various patterned layers have to be aligned vertically for the stacked layers to collectively form the monolithic structure of the IC. For each die, an optical alignment procedure is executed prior to exposing the die to the radiation pattern. Generally, the lithography system analyzes low intensity images of the radiation pattern to detect alignment marks in a layer patterned at an earlier patterning level and, based on the analysis, the optics and the movable stage are adjusted to overlay the radiation pattern with the existing patterned layers of the substrate. After completing the alignment, the resist is exposed and developed. For the initial patterning level, the radiation pattern may be aligned to an orientation of the starting substrate, as indicated, for example, by a notch in an edge of the substrate.

### SUMMARY

A method for integrated circuit (IC) fabrication, where the method includes providing a substrate including a first patterned layer and a second patterned layer, where the second patterned layer is aligned to the first patterned layer; measuring an overlay error of the second patterned layer with the first patterned layer across the substrate; based on the measuring, obtaining the overlay error of the second patterned layer with the first patterned layer; and exposing the second patterned layer to a first flux from a first location specific directional process to correct the overlay error.

A method for integrated circuit (IC) fabrication, where the method includes providing a substrate including a first patterned layer and a layer-to-be patterned disposed over the first patterned layer; coating a resist layer over the layer-to-be patterned and patterning the resist layer with a lithography process; measuring an overlay error of the patterned resist layer with the first patterned layer; etching the layer-to-be patterned using the patterned resist layer as an etch mask; and after etching the layer-to-be patterned, generating a first flux from a first location specific directional process on the layer-to-be patterned based on the measuring.

A location specific processing tool that includes a flux generator configured to generate a flux in a desired direction; a chamber having a substrate holder; and a scanning apparatus coupled to the chamber to relatively move the substrate holder with respect to the flux; a controller; a transceiver to receive an overlay error information between a second patterned layer aligned to a first patterned layer at a first plurality of locations across the second patterned layer, the first and the second patterned layers being disposed over a substrate to be processed; and a memory storing a program to be executed in the controller, the program when executed, enabling the tool to: determine location specific process conditions based on the overlay error information, and generate the flux to perform a location specific directional process with the determined location specific process conditions.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a top view of a substrate having a topmost patterned layer comprising a pattern of holes aligned to a patterned layer comprising a pattern of parallel lines at a first location where there is no overlay error, in accordance with some embodiment;

FIG. 1B illustrates a cross-sectional view of the substrate illustrated in FIG. 1A;

FIG. 1C illustrates a top view of the substrate in FIG. 1A at a second location where an overlay error of the pattern of holes in a negative x-direction is being corrected by a directional etch in a positive x-direction, in accordance with some embodiment;

FIG. 1D illustrates a cross-sectional view of the substrate illustrated in FIG. 1C;

FIG. 1E illustrates a top view of the substrate illustrated in FIG. 1C after the overlay error in the negative x-direction has been corrected;

FIG. 1F illustrates a cross-sectional view of the substrate illustrated in FIG. 1E;

FIG. 1G illustrates a top view of the substrate in FIG. 1A at a third location where an overlay error of the pattern of holes in a negative x-direction is being corrected by a directional etch in a positive x-direction, in accordance with some embodiment;

FIG. 1H illustrates a cross-sectional view of the substrate illustrated in FIG. 1G;

FIG. 1I illustrates a top view of the substrate illustrated in FIG. 1C after the overlay error in the negative x-direction has been corrected;

FIG. 1J illustrates a cross-sectional view of the substrate illustrated in FIG. 1I;

FIG. 2 illustrates a flowchart summarizing a method for pattern overlay correction, in accordance with some embodiment;

FIG. 3 illustrates a flowchart that summarizes a method for performing a location specific directional process, in accordance with some embodiment; and

FIG. 4 illustrates a flowchart summarizing a method for pattern overlay correction, in accordance with some embodiment;

### DETAILED DESCRIPTION OF ILLUSTRATIVE EMBODIMENTS

The resolution capability of a single pattern is limited by the resolution limit of the optics, λ/NA, where λ is the radiation wavelength and NA is numerical aperture. For cost-effective manufacturing at the sub-10 nm nodes, IC designs having a minimum half-pitch less than 20 nm are being fabricated using single patterning with 13.5 nm wavelength extreme ultraviolet (EUV) radiation. Thus, patterning technology is now challenged to produce patterns with a total budget for edge placement error (EPE) in single-digit nanometers, including inherent stochastic errors of EUV lithography. This squeezes a share of the EPE budget for overlay error to no more than a few nanometers, pushing overlay correction toward higher precision. Hence, further innovation in systems and methods for overlay correction is desired.

IC fabrication involves processing a substrate (typically a semiconductor wafer) through a sequence of process steps to form a stack of layers comprising multiple patterned layers at different levels in the stack. (Here, “substrate” and “wafer” are used interchangeably.) Each patterned layer has miniature structures that are aligned to previously patterned structures so that together they form a monolithic structure, which is the IC. A plurality of ICs, or dies, is fabricated on each substrate. At each patterning level, a wafer is coated with resist and, using a scanner of a lithography system, and one copy of a radiation pattern per die is printed for an array of dies. The scanner has an optical system and a movable stage with a step-and-repeat function, using which the wafer is cycled repeatedly through a sequence, in which the movable stage positions one die location of the wafer for exposure to a radiation pattern and the optical system and the stage cooperatively expose the resist at that die location. The stage is then stepped to position the next die location for exposure and the exposing is repeated. The positioning done at each die location involves aligning the radiation pattern to an existing patterned layer of the substrate. The alignment procedure performed by the scanner (described in the background section) is a pre-exposure alignment procedure, where the optics and the stage position are adjusted to reduce an overlay error of the radiation pattern prior to patterning the resist, but it does not correct any post-exposure overlay error of the patterned resist layer. This procedure of aligning the pattern at each die to alignment marks located at that die in a previously patterned reference layer is known as die-by-die alignment.

Despite the alignment done in the scanner, there is some misalignment, or, overlay error between the patterned resist and the reference layer. It is noted that, in general, this post-exposure overlay error is a location specific overlay error (i.e., the overlay error at each location in a major surface of the substrate depends on the location) and, for die-by-die alignment, the location specific overlay error naturally depends on the die locations. Nevertheless, an average overlay error may be assigned for an entire patterned layer based on the location specific overlay errors across the wafer. If no further corrective action is taken to compensate for the misalignment then the post-exposure overlay error of the patterned resist layer not only remains uncorrected but also gets carried over as post-etch overlay error to other layers patterned using one or more pattern transfer etches originating from the patterned resist layer.

This disclosure describes embodiments of systems and methods for pattern overlay correction of post-exposure and post-etch overlay errors in a patterned layer of a substrate during fabrication of an integrated circuit (IC). In various embodiments, the correction comprises performing a directional process to shift edges of patterned features (e.g., lines and holes). Since, at any location, an amount and direction of the shift depends on a location specific overlay error, the processing also has to be location specific, as explained in further detail below.

The location specific overlay error is obtained by relating each location of the substrate to a respective local overlay error based on measurements of overlay error at multiple locations of the substrate (e.g., a set of die locations distributed across the wafer). The local overlay error in a specific direction may be reduced by shifting edges of local features along that direction by an amount that compensates for the overlay error in that direction. Noting that each edge of a feature is a top boundary of a respective sidewall surface, the placement of an edge is shifted in a desired direction by shifting the respective sidewall in that direction with the location specific directional process. Using directional deposition and etching techniques, the directional process deposits or etches material in one direction to cause the sidewall to grow or recede in the desired direction, thus displacing the sidewall along with its associated edge. Each edge displacement increases or decreases a width dimension of the feature along the direction of the displacement. These location specific changes in width reduce the location specific overlay errors, thereby reducing the average overlay error of the entire patterned layer.

An incoming wafer for the location specific directional process may have a second patterned layer to be processed for pattern overlay correction, where the second patterned layer is a topmost layer of the substrate that has been aligned to a first patterned layer (the reference layer). The second patterned layer may have a replica of a radiation pattern that was either transferred directly, as is the case for a patterned resist layer, or indirectly, as is the case for a patterned hard mask layer, which has been patterned using the patterned resist layer as an etch mask. In some embodiments, a pre-exposure alignment procedure (described above) performed to align the originating radiation pattern to the first patterned layer may be the only alignment procedure that has been performed to align the second patterned layer to the first patterned layer. In some other embodiments, the second patterned layer or an etch mask used in patterning the second patterned layer may have undergone a post-exposure or post-etch pattern overlay correction in addition to the pre-exposure alignment procedure.

As mentioned above, in the embodiments described herein, post-exposure or post-etch overlay error correction is achieved by performing a location specific directional process based on measurements of overlay errors at various locations of the wafer. A process is said to be a location specific process if the value of a controlled process parameter at any location on the surface of the substrate is selected depending on the coordinates of that location. In general, a location specific process may have more than one controlled process parameter. A set of such controlled process parameters at any location describes a location specific process condition at that location. In some embodiments, the measurements of overlay errors (on which the location specific directional process for pattern overlay correction is based) may be measured on the second patterned layer. In some other embodiments, the location specific directional process for pattern overlay correction may be based on the post-exposure overlay errors measured on the patterned resist layer, whose pattern has been transferred to the second patterned layer by one or more pattern transfer etch process steps.

In one or more embodiments, the processing is performed on the second patterned layer by exposing the substrate to a flux of particles in a location specific processing tool. Although this embodiment describes processing by particles from a flux generator of the location specific processing tool, in some embodiments, radiation from, for example, a laser may be used. The tool is configured to orient the substrate relative to a direction of the particle flux such that the particles may impinge on the wafer at a non-zero angle of incidence. The substrate orientation may be controlled by tilting the wafer relative to the flux direction and rotating the wafer about a central axis normal to the major surface of the substrate.

Since the substrate may have various orientations relative to the processing tool and the particle flux, it is clarified that words commonly used in describing orientations of features in the substrate and relative positions of layers formed on the substrate, such as vertical, horizontal, above, below, top, bottom, backside, and front side, retain their usual meaning in this disclosure. That is, the major surface of the wafer is a horizontal plane and the normal to the plane is in a vertical direction; a side of the wafer in contact with a substrate holder is the backside, and a layer closer to the backside is below a layer closer to the front side.

The particles may comprise etchants or deposition precursors that may interact with the second patterned layer to etch or deposit material, as desired. The substrate is tilted such that the particle flux intersects some side of the features facing the flux, while other sides may be in a shadow region. In some embodiments, the impinging particles may remove material selectively from the second patterned layer. In some embodiments, the impinging particles may add material selectively to the second patterned layer. As explained above, etching and depositing material on a sidewall displaces the sidewall. A direction in which the processing progresses is determined by the substrate orientation relative to the flux direction. Because the flux is incident at an angle to the central axis normal to the major surface, the exposed sidewall gets shifted in a direction parallel to a projection of the flux direction onto the major surface of the second patterned layer of the wafer. A magnitude of the shift may be controlled by process parameters such as flux composition, flux energy (i.e., energy per particle), flux magnitude, substrate orientation (i.e., tilt angle and twist angle), and a total exposure time (e.g., a time for which an area of the substrate is exposed to the particle flux). As described further below, the total exposure time may be the duration of the processing for a wafer level process, where the flux is incident on the entire wafer. But, for a beam process, where the flux is incident on only a portion of the wafer, the total exposure time is a dwell time, which depends on a scan rate of a relative motion of the substrate with respect to the flux.

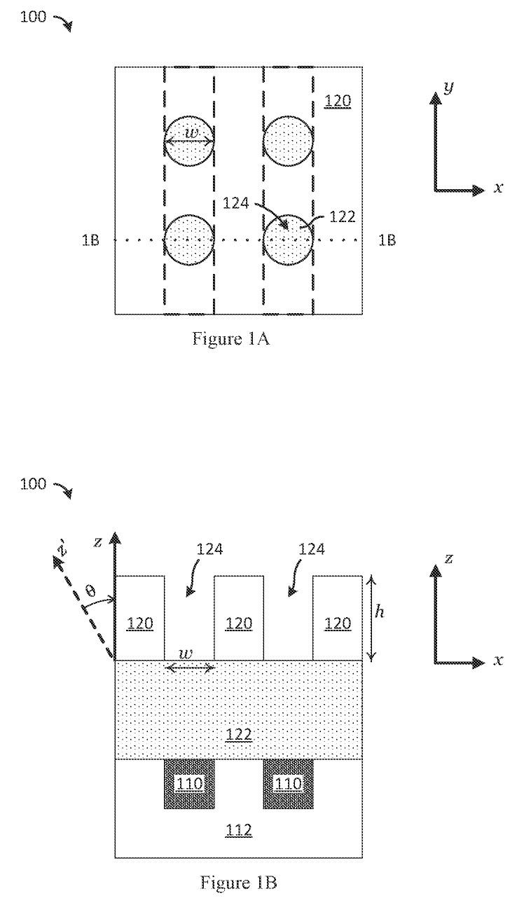

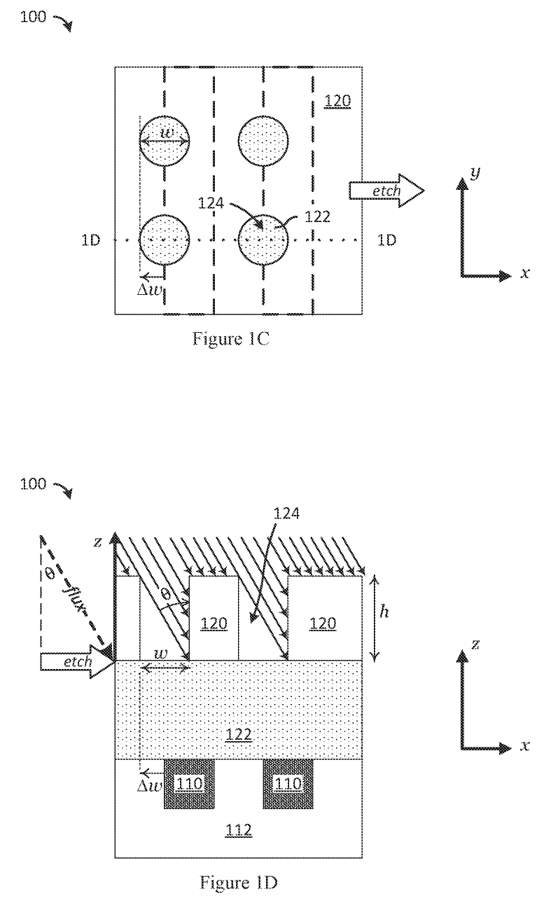

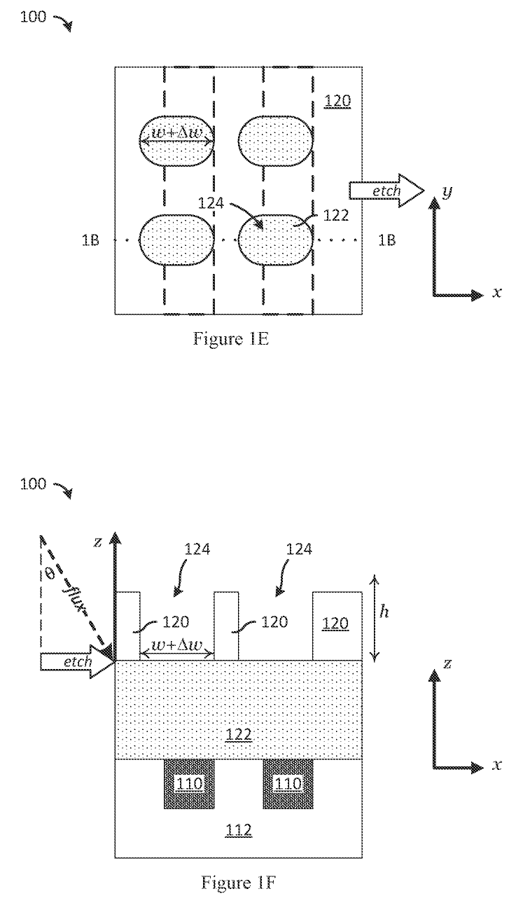

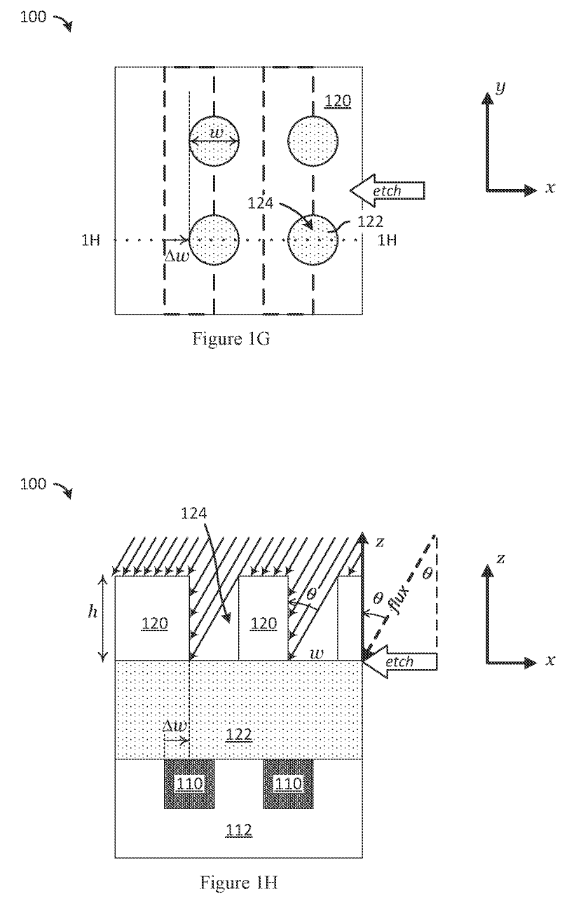

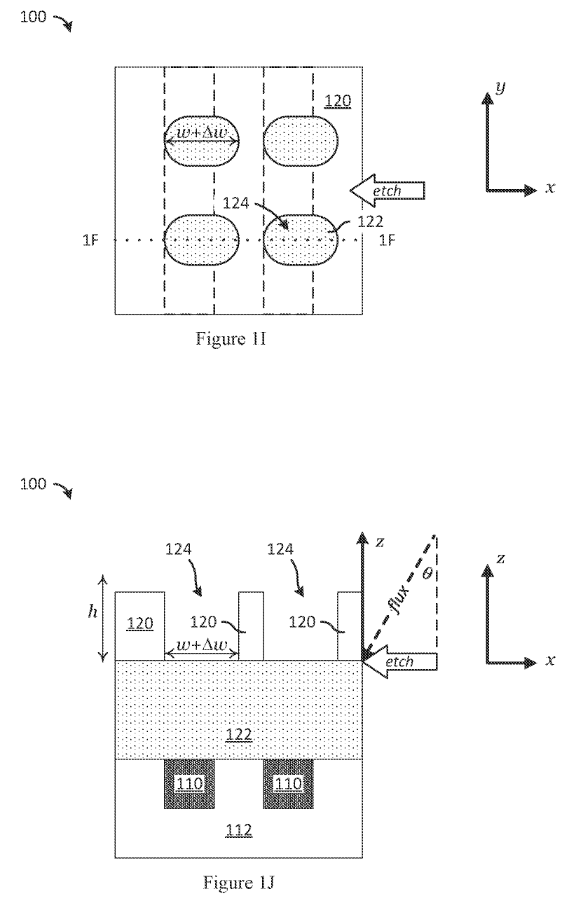

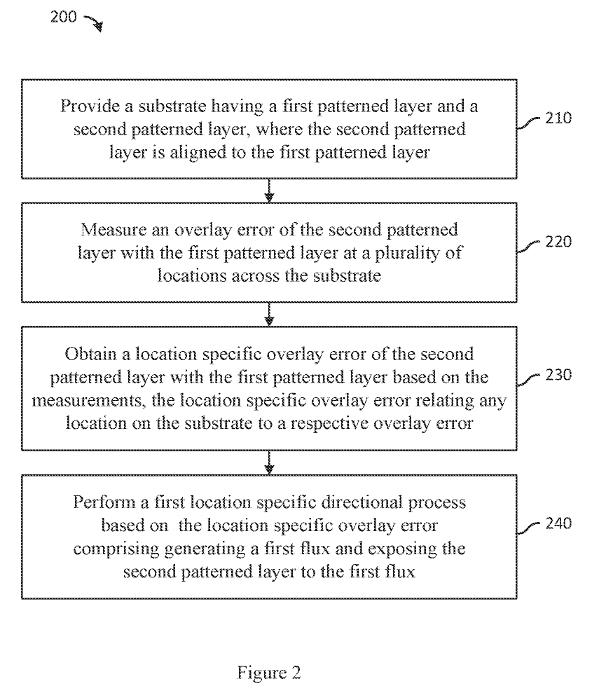

An example embodiment is illustrated in FIGS. 1A-1J. In this example, the location specific directional process is an etch process that corrects for overlay error in aligning a pattern of holes (i.e., the second patterned layer) to a pattern of lines (i.e., the first patterned layer) already formed in a layer of the substrate. The correction is achieved by etching sidewalls of the holes. The example embodiment may be of advantage when the pattern of holes is, for example, an etch mask for etching via holes in an upper interlayer dielectric (ILD2) layer for fabricating vias connecting to the pattern of lines, where the pattern of lines is a pattern of parallel metal lines already formed in the substrate inlaid in a lower interlayer dielectric (ILD1) layer.

Each via is a vertical conductor formed by filling each via hole with metal in subsequent processing steps. When properly aligned to the parallel metal lines, each via makes a low resistance electrical contact with a respective line of the pattern of parallel metal lines. If the etch mask for via holes is misaligned in a direction perpendicular to the metal lines then an area of contact between a via and a metal line is reduced, which may give rise to an undesirable high resistance tail in a distribution of via resistance, where the high resistance values are due to insufficient overlap of the vias with the metal lines. The pattern overlay correction achieved in the example embodiment may provide an advantage of reducing and even eliminating the undesirable high resistance tail.

FIG. 1A illustrates a top view and FIG. 1B illustrates a respective cross-sectional view of a substrate 100 having the second patterned layer 120 comprising a pattern of holes aligned to a first patterned layer 110 comprising a pattern of parallel lines. The views shown in FIG. 1A and FIG. 1B are at a first location of the major surface of the second patterned layer 120, where there is no overlay error. The cut plane for the cross-section is marked by a dotted line in FIG. 1A. In this example, features of the first patterned layer 110 are parallel lines formed inlaid in a first separation layer 112, as illustrated in FIG. 1B. The first patterned layer 110 in FIG. 1B may comprise parallel metal lines, and the first separation layer 112 may be the ILD1 layer, mentioned above. In some embodiments, the parallel metal lines (the first patterned layer 110) may comprise copper and the ILD1 layer (the first separation layer 112) may comprise a low dielectric constant (low-k) silicon oxide. Lateral positions of the lines of the first patterned layer 110 are indicated by dashed rectangles in FIG. 1A. A second separation layer 122 has been formed covering the first patterned layer 110 and the first separation layer 112, and the second patterned layer 120 is formed over the second separation layer 122, as illustrated in FIG. 1B. As mentioned above, the second patterned layer 120 may be a hard mask layer comprising a pattern of holes, such as the through openings 124, shaped like a circle having a width w, as shown in FIG. 1A. The through openings 124 expose a surface of the second separation layer 122. The second separation layer 122, may be the ILD2 layer, mentioned above. In some embodiments, the hard mask layer (the second patterned layer 120) may comprise silicon nitride and the ILD2 layer (the second separation layer 122) may comprise a low dielectric constant (low-k) silicon oxide.

The top view of the major surface of the second patterned layer 120 of the substrate 100 in FIG. 1A shows that, at this location, a center of each through opening 124 is positioned directly above the center of a respective line of the first patterned layer 110, as desired. Locations in the major surface may be described by rectangular coordinates (x, y) along an x-axis and a y-axis orthogonal to the x-axis, where (0, 0) is the location of a center of the major surface of the second patterned layer 120. As shown in FIG. 1A, the parallel lines of the first patterned layer 110 are parallel to the y-direction. As indicated in FIG. 1B, the z-axis is normal to the major surface. With the through openings 124 being positioned as desired relative to the lines of the first patterned layer 110, there is no overlay error to be corrected at the (x, y) location depicted in FIG. 1A. Accordingly, in the respective cross-sectional view in FIG. 1B, there is no particle flux incident on any sidewall of the through openings 124. If there were a flux, for example, at some other locations, as described further below, the flux direction would be opposite a reference direction, the reference direction being that of a z’-axis shown as a dashed arrow in FIG. 1B. The angle, θ, between the z-axis and the z’-axis, referred to as tilt angle, indicates that the substrate 100 has been tilted clockwise relative to the reference z’-direction by the tilt angle, θ.

The top view in FIG. 1C and the respective cross-sectional view in FIG. 1D are at a second location of the major surface of the second patterned layer 120 where there is an overlay error in the negative x-direction. The cut plane for the cross-section is marked by a dotted line in FIG. 1C. At this location, the center of each through opening 124 is offset by a distance Δw in the negative x-direction, instead of being directly above the center of the respective line in the first patterned layer 110, as shown in the top-view in FIG. 1C and the cross-sectional view in FIG. 1D. The overlay error undesirably reduces a vertical overlap area between each through opening 124 and the respective line in the first patterned layer 110.

In the example embodiment, a location specific directional etch process is performed at the location illustrated in FIG. 1C and FIG. 1D. The overlay error correction may be achieved by the etch process extending each of the through openings 124 toward the positive x-direction to compensate for the reduced overlap caused by the overlay error. Accordingly, the substrate 100 is tilted appropriately (as described below) and the second patterned layer 120 is exposed to a particle flux comprising etchants that etch the second patterned layer 120 selective to an exposed portion of the second separation layer 122 at the bottom of each through openings 124.

The flux may comprise a mixture of reactive species that interact chemically and inert species that interact physically with the exposed material. In some embodiments, the location specific directional etch process may comprise chemical etching, where etchants remove surface atoms by chemical interactions that form volatile products. In some embodiments, the etching may be physical etching, such as ion milling and sputter etching with a collimated particle flux, where surface atoms are mechanically dislodged by energetic particles, for example, ions accelerated by an electric field. In some embodiments, high energy inert species may be used to enhance a chemical reaction rate between the reactive species and the surface by breaking chemical bonds between the surface atoms. The chemistry may be selected such that the second patterned layer 120 (e.g., silicon nitride) is etched at a higher rate relative to the second separation layer 122 (e.g., low-k silicon oxide). The reactive species may be a reactant gas comprising atoms such as oxygen, fluorine, or chlorine, and the inert species may be an inert gas such as argon, neon, or helium. In various embodiments, the particles may be charge neutral particles (e.g., molecules and neutral radicals) or a mixture of neutral particles and charged particles (e.g., ions). In some embodiments, the gas may comprise non-interacting particles (i.e., single molecules, radicals, and ions), similar to an ideal gas. In some other embodiments, the gas may be a cluster gas comprising particles, which are clusters of atoms or molecules (e.g., about 1,000 to about 10,000 molecules) loosely bound by van der Waals forces. Clusters may be formed by a condensation induced by adiabatic expansion when, for example, compressed gas is released to a vacuum using a supersonic nozzle, resulting in a cluster gas having properties between that of a liquid and a gas. In some embodiments, the cluster gas may be ionized to acquire an average positive charge of about +1e to +10e per cluster, where e is magnitude of electron charge.

In FIG. 1D, the substrate 100 has been rotated clockwise relative to the reference z’-direction by the tilt angle, θ, same as in FIG. 1B. The normal to the major surface (i.e., the z-axis) is tilted relative to the flux direction, indicated in FIG. 1D by a dashed arrow pointing in a direction that is opposite the reference z’-direction. The incident flux is indicated schematically by solid arrows. Tilting the substrate 100 results in the flux being incident at angle of incidence equal to the tilt angle, θ. The incident flux removes material from the top surface of the second patterned layer 120, which reduces its height, h. In addition, a portion of the sidewall of the through openings 124, which is exposed to the flux, gets etched. As the etch advances, it causes the sidewall to shift laterally along a direction of the etch front, that is, along an orthogonal projection of the flux direction onto the major surface of the second patterned layer 120. The direction of the shift, referred to here as the etch direction is indicated by a block arrow in FIG. 1C and in FIG. 1D. The substrate 100 has been oriented azimuthally such that that the etch direction is parallel to the positive x-direction. The azimuthal angle, also known as twist angle may be adjusted by rotating the wafer azimuthally about a central axis normal to the major surface of the substrate. It is noted that for θ = 0° the flux is incident perpendicularly on the major surface, and increasing the tilt angle makes the flux direction less vertical, till at θ = 90° the flux is parallel to the major surface. Since the particle flux has to etch the sidewall all the way to the bottom of the through opening 124, the tilt angle has to be less than a maximum value, depending on the height, h, and the width, w, of the through opening 124.

FIG. 1E illustrates a top view and FIG. 1F illustrates a respective cross-sectional view of the substrate 100 at the location shown in FIG. 1C and FIG. 1D. The views in FIG. 1E and FIG. 1F show the state of the substrate 100 after the location specific directional etch process is complete. As explained above, the etch process has shifted the sidewall and the associated edge of the through openings 124 by a distance Δw in the positive x-direction. This edge displacement increases the width, w, of the through openings 124 at this location along the x-direction (i.e., direction of the displacement), which recovers the loss in overlap area caused by the overlay error of Δw in the negative x-direction. Note that the removal of material from the top surface of the second patterned layer 120 has reduced its height to below the original height, h.

As mentioned above, the processing described with reference to FIGS. 1C-1F is for pattern overlay correction of the second patterned layer 120, where the second patterned layer 120 may be the etch mask for etching via holes, and the second separation layer 122 may be an upper interlayer dielectric (ILD2) layer, in which the holes are to be etched. It is understood that after the location specific directional processing for pattern overlay correction is complete, an etch process using the second patterned layer 120 as the etch mask may be performed to extend the through openings 124 through the second separation layer 122 to expose a surface of the first patterned layer 110, thus forming the via holes in the ILD2 layer.

FIG. 1G and FIG. 1H illustrate a top view and a cross-sectional view of the substrate 100 at a third location of the major surface of the second patterned layer 120 where there is an overlay error in the positive x-direction. The cut plane for the cross-section is marked by a dotted line in FIG. 1G. At this location, the center of each through opening 124 is offset by a distance Δw in the positive x-direction, instead of the negative x-direction, which has been described above with reference to the top-view in FIG. 1C and the cross-sectional view in FIG. 1D. As seen in FIG. 1G and FIG. 1H, overlay error in the positive x-direction also undesirably reduces the vertical overlap between each through opening 124 and the respective line in the first patterned layer 110. Since the overlay error at this location is opposite to that in the location illustrated in FIG. 1C and FIG. 1D, the substrate 100 in FIG. 1H has been rotated counterclockwise (instead of clockwise) relative to the reference z’-direction by the tilt angle, θ. The z-axis is tilted relative to the flux direction, indicated in FIG. 1H by a dashed arrow. The twist angle has not been altered. It is noted that the reference z’-direction is always opposite the flux-direction because, in the embodiment illustrated in FIGS. 1A-1J, the tilt angle is adjusted by rotating the substrate 100 while the flux direction remains fixed. The incident flux is indicated schematically by solid arrows. Comparing the through openings 124 in FIG. 1H with those in FIG. 1D, we see that now the sidewall on the opposite side is exposed to the flux. With the particles in the incident flux impinging on the sidewall from the opposite direction, the etch direction is reversed, as indicated by a block arrow in FIG. 1G and in FIG. 1H. So, the sidewall exposed to the particle flux is shifted in the negative x-direction by the location specific directional etch process to recover the loss in overlap due to the overlap error in the positive x-direction.

FIG. 1I and FIG. 1J illustrate a top view and a respective cross-sectional view of the substrate 100 at the location shown in FIG. 1G and FIG. 1H after the etch process is complete. As explained above, the etch process has shifted the sidewall and the associated edge of the through openings 124 by a distance Δw in the negative x-direction. This edge displacement increases the width of the through openings 124 at this location from, w to (w + Δw) along the direction of the displacement to fully overlap the respective lines in the first patterned layer 110. Thus, the shift of Δw in the negative x-direction recovers the loss in overlap area caused by the overlay error of Δw in the positive x-direction. Due to the etching, the height of the second patterned layer 120 in FIG. 1J is less than the original height, h, same as in FIG. 1F.

In the example embodiment described above with reference to FIGS. 1A-1J, the substrate orientation is altered during the processing. Note that the tilt angle at the third location of the second patterned layer 120 is different from the tilt angles at the first location and the second location: The location specific directional etch process has utilized tilt angle as a controlled process parameter to achieve location specific processing. As mentioned above, a controlled process parameter of a location specific process refers to a location specific process parameter, whose value depends on the (x, y) coordinates in the major surface of the layer being processed, such as the second patterned layer 120. If the controlled parameter changes the substrate orientation then that precludes wafer level processing, since, in wafer level processing, the particle flux would be incident on the entire layer at once. Thus, in the example embodiment, the particle flux is a beam incident on a portion of the second patterned layer 120, so that the intersection area of the beam with the major surface may be moved along a trajectory in the major surface while, at the same time, the tilt angle may be varied as a function of location along the scan trajectory.

Processing a wafer by exposing the wafer to a flux incident on a portion of the topmost layer is referred to as beam processing and the process is referred to here as a beam process. The flux in a beam process is the beam, where the beam has a spot size equal to a size of the exposed portion of the layer. Clearly, the spot size of the beam is smaller than the wafer. In contrast, wafer level processing comprises exposing the topmost layer of the wafer to a flux incident on the entire topmost layer at once. Processing the entire wafer together is referred to as a wafer level process. In some embodiments, the location specific directional process is a beam process. In some other embodiments, the location specific directional process is a wafer level process.

Location specific directional processes (which include the beam processes and the wafer level processes) may be executed in a tool that can generate a directed flux, relatively move a substrate with respect to the flux, and achieve location specific process conditions that depend on a location specific overlay error determined from measurements of overlay error.

The relative motion of the substrate with respect to the flux is used to select a substrate orientation for beam processing as well as for wafer level processing. In beam processing, the relative motion of the substrate with respect to the flux is also needed for changing the location where the flux impinges on the major surface of the layer being processed. This motion, where the location may be changing along a trajectory across the wafer is referred to as scanning, the trajectory is referred to as a scan trajectory, and a rate at which the movement occurs is referred to as a scan rate.

While the substrate is moving along the scan trajectory, the scanning apparatus may be adjusting the substrate orientation by rotating the wafer. Likewise, the beam properties may be adjusted by the beam generator along the scan trajectory.

In beam processes, the scan trajectory is a sequence of locations of the substrate selected prior to processing the topmost patterned layer. The scanning motion moves the area being processed progressively through this sequence of locations. During scanning, the scanning apparatus and the beam generator may be adjusting process parameters such as the substrate orientation by rotating the wafer. Each location of the sequence of locations has an associated location specific process condition (i.e., an associated set of controlled process parameters). In other words, corresponding to the sequence of locations there is a sequence of location specific process conditions. During scanning, the location specific process condition is adjusted synchronously with the changing location of the beam on the major surface, and the second patterned layer is processed using the dynamically adjusted location specific process condition. As mentioned above, the processing may include etching material from the second patterned layer, deposit material on the second patterned layer, or perform a combination of deposition and etching at various locations along the scan trajectory.

The location specific process condition for the beam process may include a set of controlled process parameters pertaining to the relative motion of the substrate with respect to the beam such as the substrate orientation (e.g., tilt angle) and the scan rate. A rate of the processing may be controlled along the scan trajectory by having the scan rate depend on the location of the beam. In addition, the location specific process condition may include a set of controlled process parameters pertaining to properties of the flux, for example, flux composition, flux energy, flux magnitude, and total exposure time. Note that, in beam processing, the total exposure time for each location, that is, the time during which the beam is incident on that location depends on the scan rate there. The total time spent by the beam of a beam process over a unit area is referred to as dwell time and, in general, the dwell time is a location specific process parameter. In contrast, in wafer level processing, is simply a duration of the processing.

In wafer level processing, the substrate orientation is fixed during exposing the wafer to the flux. Thus, the location specific process condition, in this case, may be limited to the set of controlled process parameters pertaining to properties of the flux. The wafer level location specific directional process may implement exposure conditions that depend on the coordinates of that location in various ways. For example, in some embodiment, location specific bias voltages may be applied across the wafer using, for example, multiple electrodes positioned at various locations below a top surface of a stage over which a backside of the wafer is placed. The across wafer bias may generate a controlled across wafer variation in etching or deposition. In some embodiment, location specific processing at the wafer level may be achieved using, for example, an array of nozzles above a front side of the wafer coupled to multiple gas sources. Using nozzles of various shapes and by adjusting the gas sources independently, a controlled across wafer variation in etching or deposition may be achieved.

The processing tool, referred to as the location specific processing tool, has several components to perform a beam process or a wafer level process with location specific and directional capabilities. The location specific processing tool may include a flux generator configured to generate a flux in a desired direction, a chamber having a substrate holder, on which the wafer may be loaded to be exposed to the flux, and a scanning apparatus coupled to the chamber to relatively move the substrate holder with respect to the flux. In order to configure various components to achieve a desired location specific process condition, the location specific processing tool may include a controller, a transceiver to receive location specific overlay error information, and a memory storing a program to be executed in the controller. Executing the program enables the tool to determine location specific process conditions based on the location specific overlay error information and perform a location specific directional process with the determined location specific process conditions.

As described above, the flux may comprise various types of particles or radiation. Accordingly, the flux generator may comprise, for example, a laser, a remote plasma source, an ion source, a cluster gas source, a gas source (the gas comprising single atoms and molecules), etc. Collimators may be used in the flux generator to provide directionality to the flux. Charged particles may be directed by electromagnetic fields. Collimators for neutral particles may include compressors, pumps, and nozzles. Various beam shapes may be generated for beam processing. In some embodiments, the flux may be a beam, where the beam cross-section has a shape similar to that of a circle having a diameter smaller than the wafer diameter. In some embodiments, the flux may be a beam, where the beam has a shape similar to that of a ribbon having a width smaller than the substrate and a length stretching across the substrate.

The scanning apparatus is configured to relatively move the substrate holder with respect to the flux. As mentioned above, moving the substrate holder includes rotating the substrate holder relative to the flux to select, for example, the tilt angle and the twist angle. So, the scanning apparatus includes actuators to rotate the substrate holder relative to the flux, thereby selecting a substrate orientation of the wafer held by the substrate holder. For wafer level processing, the scanning apparatus may select an initial substrate orientation, which is not changed during a location specific directional process step: the wafer is not moved when exposed to the flux. In contrast, for beam processing, the scanning apparatus moves the substrate holder continuously with respect to the beam during the processing in order to expose various locations in the major surface of the topmost layer of the wafer. In some embodiments, where the beam process uses a location specific tilt angle (as in the example described above with reference to FIGS. 1A-1J) the scanner may also adjust the substrate orientation by rotating the wafer while, at the same time, the scanner moves the wafer along a trajectory to expose various locations of the major surface. So, the scanning apparatus for beam processing includes actuators to rotate the substrate holder relative to the beam as well as to move the major surface of the wafer through the beam.

Since the wafer is not moved during wafer level processing, the location specific wafer level processes may be performed using a wafer level tool having, for example, a rotatable substrate holder to select a direction for directional processing. The wafer level tool may be an etch tool or a deposition or a tool capable of both etch and deposition because, in some embodiments, one region of a substrate may be etched while some other region of the wafer may be deposited.

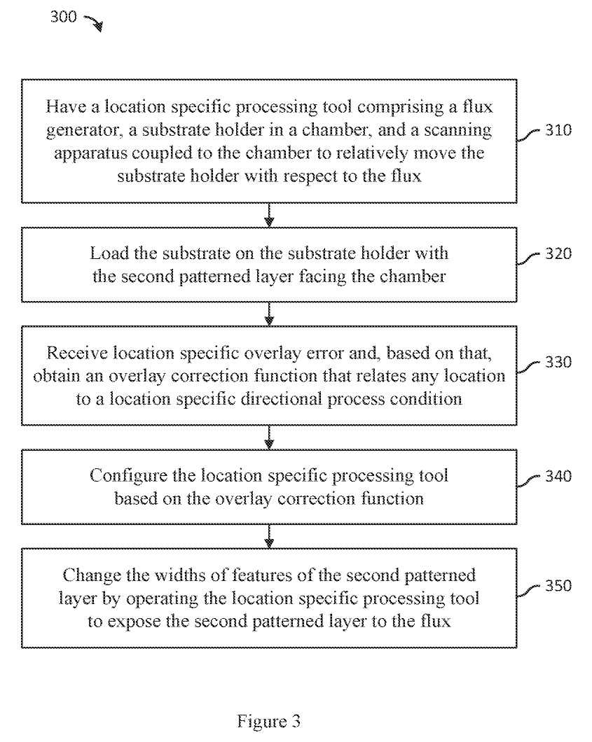

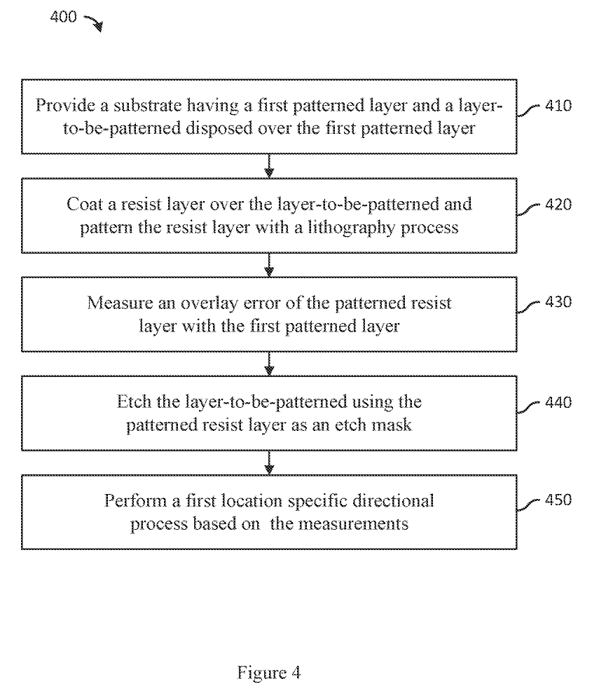

A method 200 for pattern overlay correction using location specific directional processing is summarized with reference to a flowchart illustrated in FIG. 2. It is noted that, in the method 200, the measurements of overlay errors used to obtain the location specific overlay error are done on the same patterned layer on which the location specific directional process is performed based on the obtained location specific overlay error. A method 300 for performing location specific directional processing is described with reference to a flowchart illustrated in FIG. 3. Another method 400, where the patterned layer used for measuring the overlay errors is different from the patterned layer on which the location specific directional process is performed is summarized with reference to a flowchart illustrated in FIG. 4. All of these methods are applicable to beam processing as well as wafer level processing.

As described above and indicated in block 210 of the flowchart for method 200 in FIG. 2, the incoming substrate has a first patterned layer and a second patterned layer, wherein the second patterned layer is aligned to the first patterned layer.

Overlay errors of the second patterned layer with the first patterned layer at each of a plurality of locations across the substrate are measured, as indicated in block 220.

In block 230, a location specific overlay error is obtained based on the measurements. The location specific overlay error is a relation that relates any location on the substrate to a respective overlay error. For example, the relation may be a mathematical model having model parameters that may be extracted based on the measurements.

In block 240 of the method 200, based on the location specific overlay error, the substrate is processed through a first location specific directional process comprising generating a first flux and exposing the second patterned layer to the first flux. As explained above, the processing reduces the average overlay error of the second patterned layer.

In some embodiments, the second patterned layer may be an etch mask, for example, a patterned resist layer or a hard mask layer that is used for etching a layer-to-be patterned disposed under the second patterned layer. After the etching is complete, the now patterned layer-to-be patterned may be processed by performing a second location specific directional process based on the same location specific overlay error that was used for the first location specific directional process. In some other embodiments, the processing of the second location specific directional process may be based on a second location specific overlay error, where The second location specific overlay error is based on a second set of measured overlay errors of the patterned layer-to-be patterned with the first patterned layer.

A method 300 for performing location specific directional processes, such as the first location specific directional process referred to in block 240 of the method 200 is summarized by a flowchart illustrated in FIG. 3.

As indicated in block 310, performing the location specific directional process includes having a location specific processing tool such as the location specific processing tool described in detail above. As described above, the location specific processing tool comprises a flux generator configured to generate a flux in a desired direction, a chamber having a substrate holder, and a scanning apparatus coupled to the chamber to relatively move the substrate holder with respect to the flux.

The substrate is loaded on the substrate holder with the second patterned layer facing the chamber, as indicated in block 320. The second patterned layer has multiple features, where each feature has a width along a first direction. Here, the first direction is a direction in which the processing would progress. As explained above, that would be a projection of the flux direction onto the major surface of the second patterned layer.

Block 330 summarizes a method by which location specific process conditions are obtained. The location specific processing tool receives a location specific overlay error and, based on that information, obtains an overlay correction function. The overlay correction function relates any substrate location to a respective location specific process condition. Note that in some embodiments, the received location specific overlay error may have been based on a patterned layer which is different from the layer on which the location specific directional process is to be performed. An example of such an embodiment is described below with reference to FIG. 4.

Configuring the location specific processing tool is described with reference to block 340 of the method 300. Based on the overlay correction function, a set of location specific process conditions is obtained for processing the substrate. Each location specific process condition of the set of location specific process conditions provides specific values for a set of controlled process parameters with which the respective location may be processed. In block 340, the location specific processing tool is thus configured for processing based on the overlay correction function.

As indicated in block 350 of the method 300, with the location specific processing tool configured based on the overlay correction function, the widths of the features along the first direction may be changed by operating the location specific processing tool to expose the second patterned layer to the flux specified by the location specific process conditions.

FIG. 4 illustrates a flowchart of a method 400 for pattern overlay correction, where the patterned layer used for measuring the overlay errors is different from the patterned layer on which the location specific directional process is performed.

As indicated in block 410 of the flowchart for method 400, the incoming substrate has a first patterned layer and a layer-to-be-patterned disposed over the first patterned layer.

In block 420, the layer-to-be patterned is coated with resist, and the resist layer is patterned with a lithography process, such as an extreme ultraviolet (EUV) lithography process. The EUV radiation pattern with which the resist layer is exposed is aligned to the first patterned layer during the lithography process.

After patterning the resist layer, post-exposure overlay errors of the patterned resist layer with the first patterned layer are measured, as indicated in block 430 of the flowchart for method 400. The measurements may be made at multiple locations on the patterned resist layer.

In block 440, the layer-to-be patterned may be etched using the patterned resist layer as an etch mask. After the etching is complete, the wafer is prepared for subsequent processing by stripping any remaining sacrificial layer, for example, any remaining resist or sacrificial bottom antireflective coating (BARC). After the wafer preparation, the patterned layer-to-be patterned is the topmost layer of the wafer. Hence, a location specific directional process may be performed on the patterned layer-to-be patterned using, for example, the method 300, described above with reference to FIG. 3.

As indicated in block 450 of the flowchart for method 400, a first location specific directional process is performed on the patterned layer-to-be patterned based on the measurements of overlay errors of the patterned resist layer with the first patterned layer (see block 430). Note that, in method 400, the overlay error correction (i.e., the first location specific directional process) is performed on the patterned layer-to-be patterned, while the measurements of overlay errors on which the correction is based are made on the patterned resist layer, which is different from the patterned layer-to-be patterned.

In some embodiments, before etching the layer-to-be patterned, a second location specific directional etch process may be performed on the patterned resist layer based on the overlay errors measured on the patterned resist layer. Here, the second location specific directional etch process and the first location specific directional etch process, performed subsequently, are based on the same measurements.

In this disclosure we have described methods by which pattern overlay correction may be performed by editing patterned layers using location specific directional processing. The processes described include wafer level processes and beam processes. The processes may be etch processes, or deposition processes, or a combination of etch and deposition processes. The average overlay error of a patterned layer is reduced by changing the widths of features of the patterned layer by exposing the patterned layer to a flux. The flux may be a particle flux of various types of charged and neutral particles that may interact with the patterned layer chemically and physically. In some embodiments, the flux may be a radiation flux. A patterned layer may undergo location specific directional processing at different stages of a process flow and may be processed multiple times for pattern overlay correction.

Example embodiments of the invention are described below. Other embodiments can also be understood from the entirety of the specification as well as the claims filed herein.

Example 1. A method for integrated circuit (IC) fabrication, where the method includes providing a substrate including a first patterned layer and a second patterned layer, where the second patterned layer is aligned to the first patterned layer; measuring an overlay error of the second patterned layer with the first patterned layer across the substrate; based on the measuring, obtaining the overlay error of the second patterned layer with the first patterned layer; and exposing the second patterned layer to a first flux from a first location specific directional process to correct the overlay error.

Example 2. The method of example 1, where the first location specific directional process includes a location specific directionality at an angle inclined from the normal to a major surface of the substrate.

Example 3. The method of one of examples 1 or 2, where the first location specific directional process includes an etch process or a deposition process.

Example 4. The method of one of examples 1 to 3, where the first location specific directional process includes a combination of an etch process and deposition process, where, at a first location over the second patterned layer, the first location specific directional process includes the etch process, and where, at a different second location over the second patterned layer, the first location specific directional process includes the deposition process.

Example 5. The method of one of examples 1 to 4, where the first location specific directional process includes a gas cluster beam, an ion sheet, a remote plasma process to generate a directional ion beam, or ion milling.

Example 6. The method of one of examples 1 to 5, where the first location specific directional process includes a wafer level process to correct the overlay error, and where the wafer level process includes exposing an entire major surface of the second patterned layer.

Example 7. The method of one of examples 1 to 6, where the first location specific directional process includes scanning the substrate relative to the first flux emitted by the first location specific directional process to correct the overlay error.

Example 8. The method of one of examples 1 to 7, where the overlay error includes a mathematical model.

Example 9. The method of one of examples 1 to 8, where the second patterned layer includes a sacrificial layer, a patterned resist layer, a hard mask layer.

Example 10. The method of one of examples 1 to 9, further including: etching a layer-to-be patterned disposed under the second patterned layer using the second patterned layer as an etch mask; and exposing the patterned layer-to-be patterned to a second flux from a second location specific directional process to correct the overlay error.

Example 11. The method of one of examples 1 to 10, where the second location specific directional process includes an etch process or a deposition process.

Example 12. The method of one of examples 1 to 11, where the second location specific directional process includes a combination of an etch process and a deposition process, where, at a first location over the patterned layer-to-be patterned, the second location specific directional process includes the etch process, and where, at a different second location over the patterned layer-to-be patterned, the second location specific directional process includes the deposition process.

Example 13. The method of one of examples 1 to 12, where the second location specific directional process includes a gas cluster beam, an ion sheet, a remote plasma process to generate a directional ion beam, or ion milling.

Example 14. A method for integrated circuit (IC) fabrication, where the method includes providing a substrate including a first patterned layer and a layer-to-be patterned disposed over the first patterned layer; coating a resist layer over the layer-to-be patterned and patterning the resist layer with a lithography process; measuring an overlay error of the patterned resist layer with the first patterned layer; etching the layer-to-be patterned using the patterned resist layer as an etch mask; and after etching the layer-to-be patterned, generating a first flux from a first location specific directional process on the layer-to-be patterned based on the measuring.

Example 15. The method of example 14, where the first location specific directional process includes a combination of an etch process and deposition process, where, at a first location over the layer-to-be patterned, the first location specific directional process includes the etch process, and where, at a different second location over the layer-to-be patterned, the first location specific directional process includes the deposition process.

Example 16. The method of one of examples 14 or 15, where the first location specific directional process includes a gas cluster beam, an ion sheet, a remote plasma process to generate a directional ion beam, or ion milling.

Example 17. The method of one of examples 14 to 16, where the first location specific directional process includes a wafer level process including exposing all of a major surface of the substrate to the first flux or a process in which the first flux is scanned over the major surface of the substrate.

Example 18. The method of one of examples 14 to 17, further including: before etching the layer-to-be patterned, generating a second flux from a second location specific directional etch process on the patterned resist layer based on the measuring.

Example 19. The method of one of examples 14 to 18, where the first location specific directional process includes a combination of an etch process and deposition process, where, at a first location over the patterned resist layer, the first location specific directional process includes the etch process, and where, at a different second location over the patterned resist layer, the first location specific directional process includes the deposition process.

Example 20. The method of one of examples 14 to 19, where the first location specific directional process includes a gas cluster beam, an ion sheet, a remote plasma process to generate a directional ion beam, or ion milling.

Example 21. A location specific processing tool that includes a flux generator configured to generate a flux in a desired direction; a chamber having a substrate holder; a scanning apparatus coupled to the chamber to relatively move the substrate holder with respect to the flux; a controller; a transceiver to receive an overlay error information between a second patterned layer aligned to a first patterned layer at a first plurality of locations across the second patterned layer, the first and the second patterned layers being disposed over a substrate to be processed; and a memory storing a program to be executed in the controller, the program when executed, enabling the tool to determine location specific process conditions based on the overlay error information and generate the flux to perform a location specific directional process with the determined location specific process conditions.

Example 22. The tool of example 21, where the flux is a laser beam, a gas cluster beam, or a beam of particles.

Example 23. The tool of one of examples 21 or 22, where the flux is a beam, where the beam has a circular shape having a diameter smaller than the substrate.

Example 24. The tool of one of examples 21 to 23, where the flux is a beam, where the beam has a shape similar to that of a ribbon having a width smaller than the substrate and a length stretching across the substrate.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for integrated circuit (IC) fabrication, the method comprising:
providing a substrate comprising a first patterned layer and a second patterned layer, wherein the second patterned layer is aligned to the first patterned layer;
measuring an overlay error of the second patterned layer with the first patterned layer across the substrate;
based on the measuring, obtaining the overlay error of the second patterned layer with the first patterned layer; and
exposing the second patterned layer to a first flux from a first location specific directional process to correct the overlay error.

2. The method of claim 1, wherein the first location specific directional process comprises a location specific directionality at an angle inclined from the normal to a major surface of the substrate.

3. The method of claim 1, wherein the first location specific directional process comprises an etch process or a deposition process.

4. The method of claim 1, wherein the first location specific directional process comprises a combination of an etch process and deposition process, wherein, at a first location over the second patterned layer, the first location specific directional process comprises the etch process, and wherein, at a different second location over the second patterned layer, the first location specific directional process comprises the deposition process.

5. The method of claim 1, wherein the first location specific directional process comprises a gas cluster beam, an ion sheet, a remote plasma process to generate a directional ion beam, or ion milling.

6. The method of claim 1, wherein the first location specific directional process comprises a wafer level process to correct the overlay error, and wherein the wafer level process comprises exposing an entire major surface of the second patterned layer.

7. The method of claim 1, wherein the first location specific directional process comprises scanning the substrate relative to the first flux emitted by the first location specific directional process to correct the overlay error.

8. The method of claim 1, wherein the second patterned layer comprises a sacrificial layer, a patterned resist layer, or a hard mask layer.

9. The method of claim 1, further comprising:
etching a layer-to-be patterned disposed under the second patterned layer using the second patterned layer as an etch mask; and
exposing the patterned layer-to-be patterned to a second flux from a second location specific directional process to correct the overlay error.

10. The method of claim 9, wherein the second location specific directional process comprises an etch process or a deposition process.

11. A method for integrated circuit (IC) fabrication, the method comprising:
providing a substrate comprising a first patterned layer and a layer-to-be patterned disposed over the first patterned layer;
coating a resist layer over the layer-to-be patterned and patterning the resist layer with a lithography process;
measuring an overlay error of the patterned resist layer with the first patterned layer;
etching the layer-to-be patterned using the patterned resist layer as an etch mask; and
after etching the layer-to-be patterned, generating a first flux from a first location specific directional process on the layer-to-be patterned based on the measuring.

12. The method of claim 11, wherein the first location specific directional process comprises a combination of an etch process and deposition process, wherein, at a first location over the layer-to-be patterned, the first location specific directional process comprises the etch process, and wherein, at a different second location over the layer-to-be patterned, the first location specific directional process comprises the deposition process.

13. The method of claim 11, wherein the first location specific directional process comprises a gas cluster beam, an ion sheet, a remote plasma process to generate a directional ion beam, or ion milling.

14. The method of claim 11, wherein the first location specific directional process comprises a wafer level process comprising exposing all of a major surface of the substrate to the first flux or a process in which the first flux is scanned over the major surface of the substrate.

15. The method of claim 11, further comprising:
before etching the layer-to-be patterned, generating a second flux from a second location specific directional etch process on the patterned resist layer based on the measuring.

16. The method of claim 15, wherein the first location specific directional process comprises a gas cluster beam, an ion sheet, a remote plasma process to generate a directional ion beam, or ion milling.

17. A location specific processing tool comprising:
a flux generator configured to generate a flux in a desired direction;
a chamber having a substrate holder;
a scanning apparatus coupled to the chamber to relatively move the substrate holder with respect to the flux;
a controller;
a transceiver to receive an overlay error information between a second patterned layer aligned to a first patterned layer at a first plurality of locations across the second patterned layer, the first and the second patterned layers being disposed over a substrate to be processed; and
a memory storing a program to be executed in the controller, the program when executed, enabling the tool to:
determine location specific process conditions based on the overlay error information, and
generate the flux to perform a location specific directional process with the determined location specific process conditions.

18. The tool of claim 17, wherein the flux is a laser beam, a gas cluster beam, or a beam of particles.

19. The tool of claim 17, wherein the flux is a beam, wherein the beam has a circular shape having a diameter smaller than the substrate.

20. The tool of claim 17, wherein the flux is a beam, wherein the beam has a shape similar to that of a ribbon having a width smaller than the substrate and a length stretching across the substrate.
